(19) United States
(12) Patent Application Publication
(10) Pub. No.: US 2020/0225186 A1
(43) Pub. Date: Jul. 16, 2020

(54) OFET-BASED ETHYLENE GAS SENSOR

(71) Applicant: Sumitomo Chemical Company Limited, Tokyo (JP)

(72) Inventors: Simon Goddard, Impington (GB); Nicholas Dartnell, Eltisley (GB)

(73) Assignee: Sumitomo Chemical Company Limited, Tokyo (JP)

(21) Appl. No.: 16/651,276

(22) PCT Filed: Sep. 12, 2018
(86) PCT No.: PCT/GB2018/052584

§ 371 Date: Mar. 26, 2020

(30) Foreign Application Priority Data
Sep. 28, 2017 (GB) 1715683.7

(51) Int. Cl. G01N 27/414; H01L 51/05; H01L 51/00

(52) U.S. Cl. CPC G01N 27/4141; H01L 51/0545; H01L 51/0036; H01L 51/0043; H01L 51/0007

(57) ABSTRACT

An ethylene gas sensor based on an organic field-effect transistor that includes an organic semiconductor layer incorporating a non-conducting polymer. The non-conducting polymer enhances the response of the organic field-effect transistor to presence of ethylene.

### BACKGROUND

Some embodiments of the present invention relate to gas sensors based on organic field-effect transistors (OFETs), which have an organic semiconductor layer incorporating a non-conducting polymer to enhance the response of the OFET to a gaseous analyte, and to methods of manufacture of such OFETs.

Some embodiments of the present invention relate to a method of enhancing the sensitivity of an OFET-based gas sensor, wherein the method comprises the addition of an insulating polymer to an organic semiconductor layer comprised in the OFET-based gas sensor.

In recent years, OFET-based sensors have attracted great interest due to their high selectivity and compatibility with flexible plastic substrates, offering the prospect of large-scale manufacture of OTETs on flexible substrates in a roll-to-roll process. Moreover, such OFET sensors provide low production costs due to the relatively simple device configuration of the OFETs and the instruments used for the response measurement. Therefore, OFETs are promising candidates for application as smart disposable sensor devices in health, food and environmental monitoring, diagnostics and control.

A conventional approach to optimize the response of OFET-based gas sensors to analytes includes the tailored synthesis or modification of organic semiconductor materials, which enhance the interaction between the analyte and the semiconductive material. For example, covalent integration of recognition groups onto the sensing molecules can provide specific interaction with designated analytes, thus significantly increasing the selectivity and response. In this regard, A. Lv. et al., SENSORS 17, 213 (2017) discloses an overview of functionalized semiconductive polymers for use in OFET-based sensors for detection of, inter alia, ammonia, amines, NO₂, and alcohols. United States Patent Pub. No. 2005/0150778 A1 discloses sensors comprising amine-containing materials useful for the detection of caroxylic acid-containing analytes such as fatty acids. Another approach involves the incorporation of organometallic complexes and/or metallic nanoparticles into the organic layers of the OFET-based sensor. For example, Han et al., SENSORS 16, 1763 (2016) discloses an OFET making use of a ZnO/PMMA hybrid dielectric and CuPc/pentacene heterojunction for improved response in NO₂ detection.

However, for analytes with relatively low chemical reactivity, the aforementioned optimization routes do not provide satisfactory results. One example of such an analyte is ethylene, which is produced as a product of biosynthesis in plants and serves as an indicator for the stage of ripeness of fruits and vegetables.

United States Patent Pub. No. 2013/0273665 A1 discloses that sensitivity improvement in ethylene detection may be achieved by suitably combining conductive materials, including carbon-carbon multiple bond moieties, and transition metal compounds capable of forming stable complexes with ethylene. However, beside the problem that the preparation of such types of sensors requires multiple synthesis steps and is complex, the incorporation of metal ion complexes or metal nanoparticles (such as those disclosed in U.S. Pat. No. 9,403,190 B2, for example) often results in a drop in sensor performance, or in some cases in an irreversible response.

United States Patent Pub. No. 2017/0054096 A1 discloses incorporating insulating polymers at concentrations of at least 50% by weight of the active layer into the semiconductive material of an OFET for LED or LCD device in order to improve the charge carrier mobility of the active layer. However, a solution to the aforementioned objective is not presented therein.

Therefore, it remains desirable to provide a sensing platform for analytes with low chemical reactivity such as ethylene, which may be manufactured inexpensively and in a simple manner, and which exhibit excellent sensitivity, i.e. is capable of resolving different concentrations well below 1000 ppm.

### SUMMARY

Embodiments of the present invention solves these problems with the subject matter of the claims as defined herein. The advantages of the present invention will be further explained in detail in the section below and further advantages will become apparent to the skilled artisan upon consideration of the invention disclosure.

The present inventors found that a polymer additive added to the organic semiconductor layer aids the diffusion and solubility of the gas in the OSC layer leading to an increase in the magnitude of the response to the gaseous analyte.

Generally speaking, the present invention therefore relates to a gas sensor comprising an organic field-effect transistor, the organic field-effect transistor comprising a source electrode, a drain electrode, an organic semiconductor layer connecting the source and drain electrodes, and a gate electrode separated from the organic semiconductor layer by a dielectric layer; wherein the organic semiconductor layer comprises an insulating polymer.

Further embodiments of the present invention relate to a method of enhancing the ethylene sensitivity of an OFET-based gas sensor, the method comprising the addition of an insulating polymer to an organic semiconductor layer comprised in the OFET-based gas sensor.

Another aspect of the present invention is a method of manufacturing a gas sensor comprising an OFET, wherein the OFET is prepared by providing a source electrode, a drain electrode, an organic semiconductor layer connecting the source and drain electrodes, and a gate electrode separated from the organic semiconductor layer by a dielectric layer; wherein the organic semiconductor layer is provided by dissolving the organic semiconductor and an insulating polymer in one or more solvents, and depositing the organic semiconductor layer from the obtained solution.

Preferred embodiments of the gas sensor according to the present invention and other aspects of the present invention are described in the following description and the claims.

### BRIEF DESCRIPTION OF THE DRAWINGS

FIG. 1A illustrates the general architecture of a bottom gate/bottom contact OFET-based sensor.

FIG. 1B illustrates the general architecture of a bottom gate/top contact OFET-based sensor.

FIG. 1C illustrates the general architecture of a top gate/bottom contact OFET-based sensor.

FIG. 1D illustrates the general architecture of a top gate/top contact OFET-based sensor.

FIG. 2A illustrates the configuration of the bottom gate/bottom contact OFET-based sensor used in Examples 1 and 2.

FIG. 2B illustrates the configuration of the bottom gate/top contact OFET-based sensor used in Examples 3 to 5.

FIG. 3 is a graph showing the percentage change in current on the application of ethylene (500 ppm) and the recovery after ethylene removal.

FIG. 4 is a graph showing the percentage change in current as a function of ethylene concentration for a bottom gate/bottom contact OFET according to Example 1.

### DETAILED DESCRIPTION

For a more complete understanding of the present invention, reference is now made to the following description of the illustrative embodiments thereof.

In some embodiments, a gas sensor comprising an organic field-effect transistor (OFET) is provided, where the organic field-effect transistor comprises a source electrode, a drain electrode, an organic semiconductor layer connecting the source and drain electrodes, and a gate electrode separated from the organic semiconductor layer by a dielectric layer, and the organic semiconductor layer comprises an insulating polymer.

The wording “organic field-effect transistor” (OFET), as used herein, denotes field-effect transistors using organic material as the semiconductive material. If the components of the OFET are deposited in thin films, such devices are known as “organic thin film transistors” (OTFTs).

In general, the sensors described in the present application are directed at gaseous or volatile analytes, which may be borne in a gaseous medium (for instance, as vapor) or transported by itself (then the analyte may represent the gaseous medium or one component of a mixture making up the gas or liquid). While not being limited thereto, a specific example of a gas sensor of the present invention is an ethylene sensor.

The gas sensor of the present invention is characterized in that the OFET comprises an organic semiconductor layer containing an insulating polymer additive, which may advantageously provide an enhanced response to the gaseous analyte (such as ethylene), due to the incorporation of the insulating polymer additive increasing the number and/or density of analyte capture sites in the organic semiconductor layer providing an increase in the diffusion and concentration of gaseous analyte in the OSC film. Additionally, swelling of the insulating polymer in the presence of the gaseous analyte, may induce a change in the charge carrier mobility of the organic semiconductor material.

From the viewpoint of optimized device yields and performance (e.g. high and stable drain current), it is preferable that the insulating polymer additive is comprised at a content of 0.01 to 5 wt.-% based on the total weight of the organic semiconductor layer, further preferably at a content of 0.02 to 2 wt.-%, especially preferably at a content of 0.05 to 1 wt.-%, based on the total weight of the organic semiconductor layer. Surprisingly, organic semiconducting layers comprising insulating polymers at levels of 0.1 weight per cent of the organic layer or less provided an increased response of the OTFT to ethylene. At such low levels, the insulating semiconductors were found not to adversely affect the OTFT operation. This effect of the low percentage weight of insulating polymer in the organic semiconducting layer may be explained by the fact that the insulating polymer additive swells in the presence of ethylene leading to a change in the charge carrier mobility of the organic semiconductor.

The insulating polymer is not particularly limited any may be suitably selected by the skilled artisan depending on its processability and its capability of dissolving the gaseous analyte. In preferred embodiments, the insulating polymer is selected from at least one of the group consisting of poly(alkylene oxide), polystyrene, polyethylene, polypropylene, polyvinylpyridine, polylactic acid, and poly(methyl methacrylate), further preferably from at least one of the group consisting of poly(alkylene oxide) (e.g. poly(ethylene oxide)), polystyrene, and polyethylene, particularly due to their good solubility for ethylene. It is noted that the insulating polymer is present in the organic semiconductor layer in a physical mixture with the organic semiconductor material. While not being limited thereto, the mass-average molecular weight Mw of the insulating polymer is preferably between 1·10⁴ and 1·10⁶.

In principle, all known organic semiconducting materials are suitable for use in the OFET organic semiconductor layer comprised in the gas sensor of the present invention. For instance, a p-type OFET device can be formed by selecting a semiconductive material, which is efficient at accepting, conducting, and donating holes, and selecting a material for the source and drain electrodes which is efficient at injecting and accepting holes from the semiconductive material. Good energy-level matching of the Fermi-level in the electrodes with the HOMO level of the semiconductive material can enhance hole injection and acceptance. In contrast, an n-type device can be formed by selecting a semiconductive material which is efficient at accepting, conducting, and donating electrons, and selecting a material for the source and drain electrodes which is efficient at injecting electrons into and accepting electrons from the semiconductive material.

The n-type organic semiconductor is not particularly limited and may be suitably selected from electron accepting materials known to the skilled artisan. Examples of n-type organic semiconductors for use in the OFET may comprise fullerenes and fullerene derivatives. Preferably, the n-type organic semiconductor may be selected from C₆₀, C₇₀, C₉₆, PCBM-type fullerene derivatives (including phenyl-C61-butyric acid methyl ester (C₆₀PCBM), TCBM-type fullerene derivatives (e.g. tolyl-C61-butyric acid methyl ester (C₆₀TCBM)), ThCBM-type fullerene derivatives (e.g. thienyl-C61-butyric acid methyl ester (C₆₀ThCBM). Further examples of fullerene derivatives that may be used in the OFET, in accordance with the present application, include those disclosed in WO 2004/073082 A1, U.S. 2011/0132439 A1, WO 2015/036075 A1, and U.S. 2011/0132439 A1. Further, it is understood that the n-type organic semiconductor may also consist of a mixture of a plurality of the above mentioned electron accepting materials.

The p-type organic semiconductor is likewise not particularly limited and may be appropriately selected from standard electron donating materials that are known to the person skilled in the art and are described in the literature. In a preferred embodiment, the p-type organic semiconductor may be an organic conjugated polymer, which can be a homopolymer or copolymer including alternating, random or block copolymers. Preferred are non-crystalline or semi-crystalline conjugated organic polymers. As exemplary p-type organic semiconducting polymers, polymers selected from conjugated hydrocarbon or heterocyclic polymers including polyacene, polyaniline, polyazulene, polybenzofuran, polyfluorene, polyfuran, polyindenofluorene, polyindole, polyphenylene, polypyrazoline, polypyrene, polypyridazine, polypyridine, polytriarylamine, poly(phenylene vinylene), poly(3-substituted thiophene), poly(3,4-bisubstituted thiophene), polyselenophene, poly(3-substituted selenophene), poly(3,4-bisubstituted selenophene), poly(bisthiophene), poly(terthiophene), poly(bisselenophene), poly(terselenophene), polythieno[2,3-b]thiophene, polythieno[3,2-b]thiophene, polybenzothiophene, polybenzo[1,2-b:4,5-b′]dithiophene, polyisothianaphthene, poly(monosubstituted pyrrole), poly(3,4-bisubstituted pyrrole), poly-1,3,4-oxadiazoles, polyisothianaphthene, derivatives and co-polymers thereof may be mentioned. Preferred examples of p-type OSCs include copolymers of polyfluorenes and polythiophenes, each of which may be substituted, and polymers comprising benzothiadiazole-based and thiophene-based repeating units, each of which may be substituted. In general, it is understood that the p-type organic semiconductor may also consist of a mixture of a plurality of electron donating materials.

The material used for the dielectric layer is not particularly limited and may be suitably selected by the skilled artisan from organic or inorganic insulating materials having a high resistivity. In order to achieve high drain currents OTFTs with thin dielectric layers in the channel region are preferred. The thickness of the insulating layer is preferably less than 2 μm, more preferably less than 500 nm. Examples of inorganic materials include, but are not limited to SiO₂, SiNx and spin-on-glass (SOG) type materials. Preferred organic materials are generally polymers and include, but are not limited to, insulating polymers such as poly(vinylalcohol) (PVA), polyvinylpyrrolidine (PVP), acrylates such as polymethylmethacrylate (PMMA) and benzocyclobutanes (BCBs), as well as copolymers derived therefrom. The insulating layer may be formed from a variety of materials or comprise a multi-layered structure.

The OFET structures may be provided on rigid and flexible substrates, including layers of plastic films such as polyethylene terephthalate, polyethersulfone, polyethylenenaphthalate, polyimide, polyetherimide, polystyrene, polyvinyl chloride, polyethylene, polypropylene, nylon and polycarbonate, glass substrates such as quartz, and silicon wafers.

The gate electrode can be composed of a wide range of conducting materials, including metals (e.g. aluminum, gold, chromium or silver), metal compounds (e.g. indium tin oxide), conductive polymers (such as polystyrene sulfonate-doped poly(3,4-ethylenedioxythiophene) (PSS-PEDOT)), and conducting ink/paste comprised of carbon black/graphite. The thickness of the gate electrode ranges for example from about 5-500 nm, preferably between 10 and 300 nm, for metal films and from about 10 nm to about 10 μm for conductive polymers.

The material for the source and drain electrodes is likewise not particularly limited and includes metals (e.g. platinum, gold, silver, nickel, chromium, copper, iron, tin, antimony, lead, tantalum, indium, palladium, tellurium, rhenium, iridium, aluminum, ruthenium, germanium, molybdenum, tungsten, zinc, lithium, beryllium, sodium, magnesium, potassium, calcium, scandium, titanium, manganese, zirconium, gallium, niobium, sodium, magnesium, lithium and their alloys), metal oxides (tin oxide-antimony, indium tin oxide, fluorine-doped zinc oxide), carbon, graphite, glassy carbon, carbon paste. Also, conductive polymers having a conductivity of greater than 10⁻³ S/cm may be used as source or drain electrode material, which include, but are not limited to, polyaniline, polypyrrole, PSS-PEDOT, or their derivatives or their mixtures, which may also be doped for enhanced conductivity.

The source and drain electrodes may be identical or may differ from each other in terms of selected materials, physical properties and/or surface treatment.

In preferred embodiments, at least a part of a surface of the source electrode and/or the drain electrode may be modified with a compound having a functional group with an electron-withdrawing property. In the case where surface preparation of the source electrode and the drain electrode is performed with a compound having a functional group with an electron-withdrawing property, work functions of the source electrode and the drain electrode can be made high even if a rare metal material is not used. Examples of compounds having an electron-withdrawing property are disclosed in United States Patent Pub. No. 2009/00575656 A1 and include thiols, disulfides, sulfides and silane coupling agents. In further preferred embodiments, particularly when using the gas sensor as an ethylene sensor, the compound having the functional group with the electron-withdrawing property is a thiol, preferably a fluorobenzenethiol (e.g. 4-fluorobenzenethiol), which further has the advantage that it blocks the response to the gaseous analyte 1-methylcyclopropene and thus enables selective ethylene detection in presence of both analytes.

OTFTs are generally classified as bottom-gate and top-gate OTFTs, each of which may have a top or bottom contact configuration.

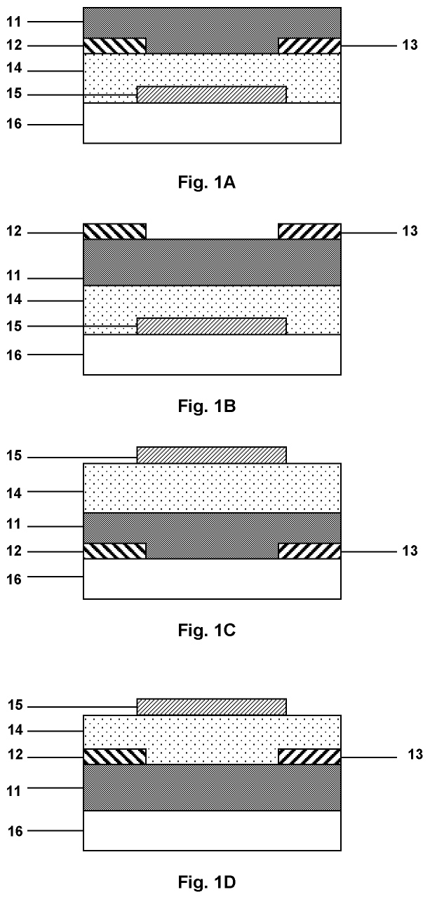

FIG. 1A illustrates the general architecture of a bottom-gate/bottom contact organic thin film transistor (OTFT), which comprises a gate electrode 15 deposited on a substrate 16. An insulating layer 14 of dielectric material is deposited over the gate electrode 15 and source and drain electrodes 12, 13 are deposited over the insulating layer 14 of dielectric material. The source and drain electrodes 12, 13 are spaced apart to define a channel region therebetween, which is located over the gate electrode 15. An organic semiconductor material 11 is deposited in the channel region for connecting the source and drain electrodes 12, 13. The organic semiconductor layer 11 may extend at least partially over the source and drain electrodes 12, 13.

FIG. 1B shows the general architecture of a bottom-gate/top contact organic thin film transistor (OTFT), which differs from the configuration of FIG. 1A in that the source and drain electrodes 12, 13 are located on top of the organic semiconductor layer 11.

Alternatively, it is known to provide a gate electrode at the top of an organic thin film transistor to form a so-called top-gate organic thin film transistor. In a top-gate/bottom contact configuration, which is illustrated by FIG. 1C, source and drain electrodes 12, 13 are deposited on a substrate 16 and spaced apart to define a channel region therebetween. A layer of an organic semiconductor material 11 is deposited in the channel region to connect the source and drain electrodes 12, 13 and may extend at least partially over the source and drain electrodes 12, 13. An insulating layer of dielectric material 14 is deposited over the organic semiconductor layer 11 and may also extend at least partially over the source and drain electrodes 12, 13. A gate electrode 15 is deposited over the dielectric layer 14 and located over the channel region.

A top-gate configuration, wherein the source and drain electrodes 12, 13 are positioned over the organic semiconductor layer 11 is known as top-gate/top contact architecture (see FIG. 1D).

In a preferred embodiment of the gas sensor of the present invention, the OFET is a bottom-gate OTFT, which may be either of the bottom- or top-contact type.

It is understood that FIGS. 1A to 1D merely illustrate the relative positions of the essential layers and that other layers may be included in the device architectures.

For example, a self assembled monolayer (SAM) may be provided on the gate, source and drain electrodes, and/or on the substrate, insulating layer and organic semiconductor material in order to promote crystallinity, reduce contact resistance, repair surface characteristics and promote adhesion, if necessary. Exemplary materials for such a monolayer include, but are not limited to, chloro- or alkoxysilanes with long alkyl chains, e.g. octadecyltrichlorosilane. Alternatively or in addition, the structure may comprise additional organic or inorganic intermediate layers, in particular an intermediate layer located between the dielectric layer and the semiconducting layer or between the dielectric layer and the gate electrode, which may reduce/inhibit operational drift resulting from ions possibly present within the dielectric, serve as analyte-selective membranes, as layers for enhancing charge injection or serve other purposes supporting the sensor function. A preferred example of such an intermediate layer is a metal oxide layer (e.g. Al₂O₃) positioned between the gate electrode and the dielectric layer.

In a second embodiment, the present invention relates to a method of enhancing the ethylene sensitivity of an OFET-based gas sensor. Said method is characterized in that it comprises the addition of an insulating polymer to an organic semiconductor layer comprised in the OFET-based gas sensor. It is understood that the preferred features of the first embodiment likewise apply to the method of the second embodiment.

In a third embodiment, the present invention relates to a method of manufacturing a gas sensor comprising an OFET, the OFET being prepared by providing a source electrode, a drain electrode, an organic semiconductor layer connecting the source and drain electrodes, and a gate electrode separated from the organic semiconductor layer by a dielectric layer; wherein the organic semiconductor layer is provided by dissolving the organic semiconductor and an insulating polymer in one or more solvents, and depositing the organic semiconductor layer the obtained solution. It is understood that the preferred features of the first embodiment likewise apply to the method of the third embodiment, i.e. that the method of the third embodiment may be used to manufacture a gas sensor as described above in combination with the first embodiment.

In general, the dielectric layer and the source, drain and gate electrodes for OFET preparation may be provided by known methods which may be suitably selected by the skilled artisan depending on the chosen materials. For example, metal layers may be deposited by electron beam methods, sputtering, coating, evaporation (e.g. vacuum evaporation) and solution deposition (e.g. by using metal-filled polymer solutions) methods. Metal oxide layers (as intermediate layers, for example) may be further prepared by anodization, reactive ion etch or by UV/ozone treatments. Organic materials (including the organic semiconductor layer or source and drain electrode surfactants) are preferably deposited by using solution deposition techniques which include, but are not limited to, coating or printing or microdispensing methods like for example spin coating, spray coating, web printing, brush coating, dip coating, slot-die printing, ink jet printing, letter-press printing, stencil printing, screen printing, doctor blade coating, roller printing, offset lithography printing, flexographic printing, or pad printing.

In some cases it may be necessary to dissolve the organic semiconductor and the insulating polymer in different solvents prior to the deposition of the organic semiconductor layer, which may be suitably selected by the skilled artisan in view of their compatibility, boiling point and the processing conditions. In addition, a blend of multiple solvents may be used for each of the species to be dissolved. In a preferred embodiment, specifically in the fabrication of ethylene sensors, the one or more solvents used for dissolving the organic semiconductor and the insulating polymer include 1,2,4-trimethylbenzene and/or ortho-dichlorobenzene.

Overall, it will be appreciated that the preferred features of the first and second embodiments specified above may be combined in any combination, except for combinations where at least some of the features are mutually exclusive. Merely by way of example, the following are some examples of sensors, in accordance with some embodiments of the present disclosure.

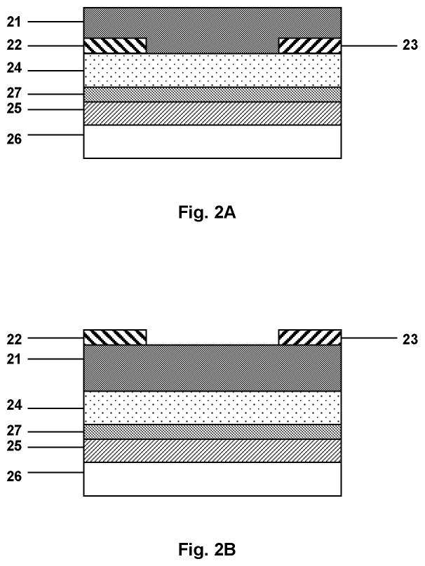

FIG. 2A illustrates an OTFT (hereinafter referred to as Example 1), in accordance with some embodiments of the present disclosure, having a bottom-gate/bottom contact structure. The OTFT was provided by vapour-depositing an aluminium layer (having a thickness of 200 nm) onto a flexible PEN substrate to serve as a gate electrode. An intermediate layer 27, comprising aluminium oxide layer (Al₂O₃), was formed by an anodization treatment of the aluminium to achieve a thickness of 5 nm. A polymeric dielectric material was spin-coated on the intermediate layer to achieve a thickness of 60 nm and heated to crosslink the material to create a low dielectric constant at the OSC interface to enhance mobility.

Gold source and drain electrodes were evaporated (W=4 mm, L=140 μm) and subsequently treated with 4-fluorobenzenethiol. For the preparation of the organic semiconductor layer, an organic semiconductor material and poly(ethylene oxide) (M_{w}=100 000) were dissolved in a blend of 1,2,4-trimethylbenzene (80% v/v) and ortho-dichlorobenzene (20% v/v) and spin coated to give an organic semiconductor layer having a thickness of 40 nm. As organic semiconductor material, a p-type semiconducting co-polymer having the following chemical formula was used:

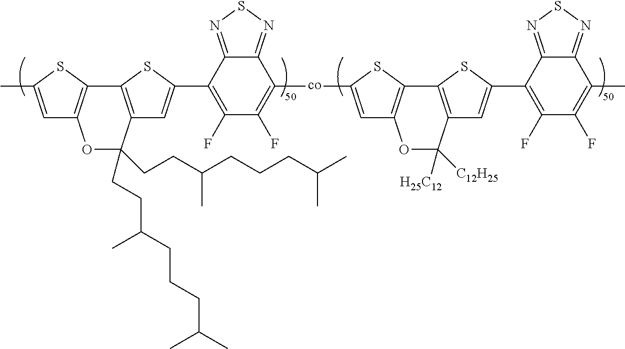

The content of poly(ethylene oxide) was 0.1 wt.-% based on the total weight of the organic semiconductor layer.

Comparative Example 1 was prepared in the same manner as the OTFT of Example 1, with the exception that the organic semiconductor layer was prepared by depositing the organic semiconductor from a 1,2,4-trimethylbenzene solution without the use of poly(ethylene oxide).

The OTFTs of Example 1 and Comparative Example 1 were equilibrated in a dry nitrogen flow (100 ml·min⁻¹) for one hour whilst applying V_{g} of −4 V and V_{ds} of −4 V for a duration of 0.1 s every 25 s and measuring the drain current (I_{d}).

After one hour the gas supply was changed to ethylene diluted in nitrogen. The flow rate remained constant (100 ml·min⁻¹). After one hour of ethylene/nitrogen flow the flow was returned to pure dry nitrogen for 4 hours. The nitrogen-ethylene-nitrogen cycle was then repeated. On application of the ethylene/nitrogen mix there was a reduction in drain current, which then increased again when the flow was returned to pure nitrogen.

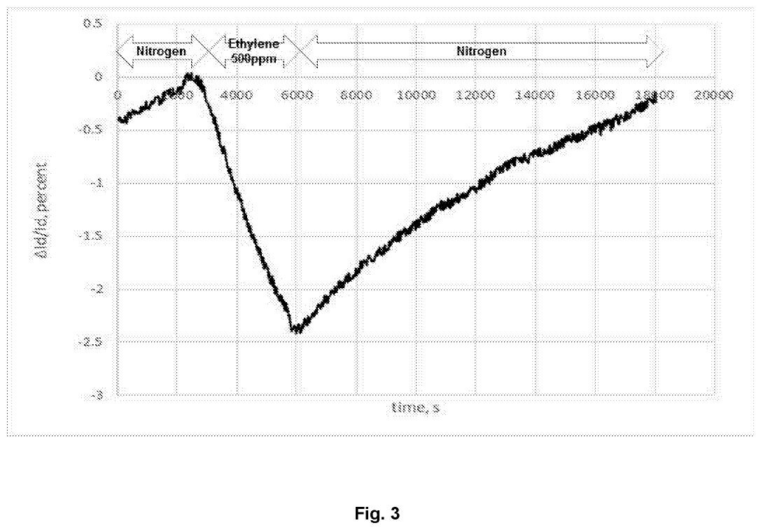

FIG. 3 shows the change in current of the OTFTs of Example 1 and Comparative Example 1 for the application of 500 ppm of ethylene in nitrogen and the recovery in current when the ethylene is removed.

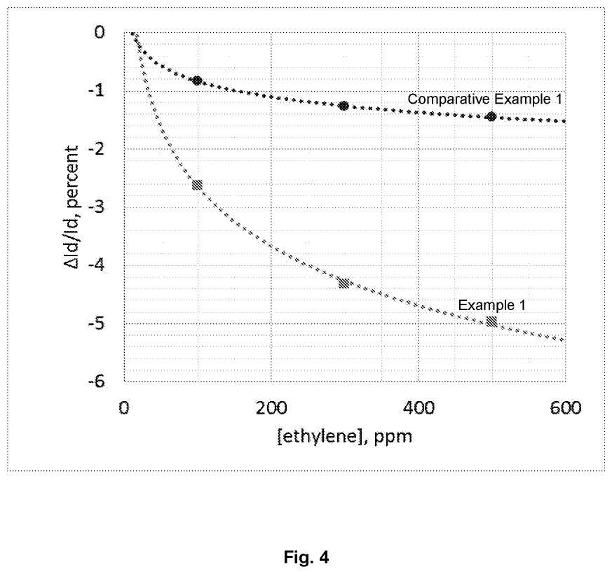

FIG. 4 shows the response to ethylene gas of the OTFTs of Example 1 and Comparative Example 1 at 3 concentrations for TFTs with and without 0.1 wt.-% PEO in the OSC layer.

These results show that the response to ethylene is significantly improved throughout the entire concentration range with incorporation of 0.1 wt.-% poly(ethylene oxide) in the organic semiconductor layer.

An additional experiment was performed to identify whether the increase in ethylene response in Example 1 relative to Comparative Example 1 was due to the different solvent compositions or due to the addition of PEO:

In Comparative Example 2, three OTFTs were prepared according to Comparative Example 1. In Comparative Example 3, two OTFTs were prepared according to Comparative Example 1, with the exception that ortho-dichlorobenzene has been used as a solvent instead of 1,2,4-trimethylbenzene. In Example 2, an OTFT was prepared according to Comparative Example 3, with the exception that 0.05 wt.-% PEO was added in the organic semiconductor layer.

The ethylene response of the OTFTs according to Comparative Examples 2 and 3 and Example 2 has been measured, using an analyte with an ethylene concentration of 1000 ppm in nitrogen. The results are shown in Table 1 below.

TABLE 1

| | | | Response, [%] (ΔId/Id) |
|---|---|---|---|
| | Type of | PEO addition | Ethylene |
| | OSC solvent | (0.05 wt-%) | (1000 ppm in nitrogen) |
| Comparative | TMB | No | 1.31 |
| Example 2 | | | 1.25 |
| | | | 1.01 |
| Comparative | o-DCB | No | 1.06 |
| Example 3 | | | 1.16 |
| Example 2 | o-DCB | Yes | 4.47 |

The results demonstrate that OTFTs with an organic semiconductor layer prepared from either TMB or o-DCB, in accordance with some embodiments of the present disclosure, show a similar response to ethylene, and that an increase in ethylene response is only observed when the insulating polymer additive is introduced.

In a further series of experiments, different insulating polymer additives were studied:

In Example 3, an OTFT having a bottom-gate/top contact structure, as illustrated in FIG. 28, was prepared. An aluminium layer (having a thickness of 200 nm) was vapour-deposited onto a flexible PEN substrate to serve as a gate electrode, and an aluminium oxide layer (Al₂O₃) was formed by an anodization treatment of the aluminium to achieve a thickness of 5 nm. Thereafter, a polymeric dielectric material was spin-coated on the intermediate layer to achieve a thickness of 60 nm and heated to crosslink the material. For the preparation of the organic semiconductor layer, an organic semiconductor material (p-type material as used in Example 1) and poly(ethylene oxide) (M_{w}=100 000) were dissolved in a blend of 1,2,4-trimethylbenzene (80% v/v) and ortho-dichlorobenzene (20% v/v) and spin coated to give an organic semiconductor layer having a thickness of 40 nm and a content of poly(ethylene oxide) of 0.1 wt.-% based on the total weight of the organic semiconductor layer. Gold source and drain electrodes were evaporated (W=4 mm, L=40 μm) without treatment with 4-fluorobenzenethiol.

In Example 4, an OTFT was prepared in the same manner as Example 3, with the exception that polyethylene (M_{w}=35 000) was used as insulating polymer additive instead of PEO and 1,2,4-trimethylbenzene was used as a single solvent. In Example 5, an OTFT was prepared in the same manner as Example 4, with the exception that polystyrene (M_{w}=650 000) was used as an insulating polymer additive. Comparative Example 4 was prepared in the same manner as Examples 4 or 5, with the exception that no insulating polymer was added.

The ethylene response of the OTFTs was measured, using an ethylene concentration of 1000 ppm in dry nitrogen at a flow rate of 50 ml·min⁻¹. The percentage change in drain current on addition of the ethylene to a background of dry nitrogen is shown in Table 2 below. The range of values for the ethylene response was for the measurement of different TFTs prepared by the same method.

TABLE 2

| | Polymeric | Ethylene response | Number of |
|---|---|---|---|
| | additive | [%] | measurements |
| Comparative | no polymeric | 1.5 to 2.9 | 2 |
| Example 4 | additive | | |
| Example 3 | 0.1 wt.-% | 3.7 to 8.9 | 7 |
| | poly(ethylene | | |
| | oxide) (MW 100k) | | |
| Example 4 | 0.1 wt.-% | 4.6 to 7.1 | 2 |
| | polyethylene | | |
| | (MW 35k) | | |
| Example 5 | 0.1 wt.-% | 4.3 to 12.3 | 3 |
| | polystyrene | | |
| | (MW 650k) | | |

Table 2 demonstrates that both polyethylene and polystyrene lead to an increase in ethylene response similar to PEO (compared to Comparative Example 4 without polymer additive in the OSC) when added at the same concentration in the OSC film (0.1%).

In view of the above, it has been shown that the present invention provides a sensing platform for analytes with low chemical reactivity, which exhibits excellent sensitivity, and which may be manufactured inexpensively and in a simple manner.

Once given the above disclosure, many other features, modifications, and improvements will become apparent to the skilled artisan.

### REFERENCE NUMERALS

11/21 organic semiconductor layer
12/22 source electrode
13/23 drain electrode
14/24 dielectric layer
15/25 gate electrode
16/26 substrate
27 intermediate layer

1. A gas sensor configured for sensing ethylene, comprising:
an OFET, wherein the OFET comprises a source electrode, a drain electrode, an organic semiconductor layer connecting the source and drain electrodes, and a gate electrode separated from the organic semiconductor layer by a dielectric layer, and wherein the organic semiconductor layer comprises an insulating polymer and the organic semiconductor layer comprises an insulating polymer additive at a content of 0.01 to 5 weight percent (wt-%) based on a total weight of the organic semiconductor layer.

2. The gas sensor according to claim 1, wherein the insulating polymer is selected from at least one of the group consisting of poly(alkylene oxide), polystyrene, polyethylene, polypropylene, polyvinylpyridine, polylactic acid, and poly(methyl methacrylate), preferably from at least one of the group consisting of poly(ethylene oxide), polystyrene, and polyethylene.

3. The gas sensor according to either of claim 1, wherein the insulating polymer additive is comprised at a content of 0.02 to 2 wt.-%, at a content of 0.05 to 1 wt.-% or at a content of 0.1 wt.-% or less, based on the total weight of the organic semiconductor layer.

4. The gas sensor according to claim 1, wherein the OFET comprises a bottom gate organic thin-film transistor.

5. The gas sensor according to claim 1, wherein at least a part of a surface of the source electrode and/or the drain electrode is modified with a compound having a functional group with an electron-withdrawing property.

6. The gas sensor according to claim 5, wherein the compound having the functional group with the electron-withdrawing property comprises a thiol.

7. The gas sensor according to claim 6, wherein the compound having the functional group with the electron-withdrawing property comprises a fluorobenzenethiol.

8. A method for enhancing ethylene sensitivity of an OFET-based gas sensor, the method comprising:
adding less than 5 weight percent of an insulating polymer to an organic semiconductor layer of the OFET-based gas sensor.

9. The method according to claim 8, wherein the insulating polymer is selected from at least one of the group consisting of poly(ethylene oxide), polystyrene, polyethylene, polypropylene, polyvinylpyridine, polylactic acid, and poly(methyl methacrylate), preferably from at least one of the group consisting of poly(ethylene oxide), polystyrene, and polyethylene.

10. A method for manufacturing an ethylene gas sensor comprising:
providing an OFET, the OFET being prepared by providing a source electrode, a drain electrode, an organic semiconductor layer connecting the source and drain electrodes, and a gate electrode separated from the organic semiconductor layer by a dielectric layer; wherein the organic semiconductor layer is provided by dissolving the organic semiconductor and less than 5 weight percent of an insulating polymer in one or more solvents, and depositing the organic semiconductor layer from the obtained solution.

11. The method for manufacturing the ethylene gas sensor according to any 10, wherein the insulating polymer is selected from at least one of the group consisting of poly(ethylene oxide), polystyrene, polyethylene, polypropylene, polyvinylpyridine, polylactic acid, and poly(methyl methacrylate), preferably from at least one of the group consisting of poly(ethylene oxide), polystyrene, and polyethylene.

12. The method of manufacturing the ethylene gas sensor according to claim 10, wherein the one or more solvents comprise 1,2,4-trimethylbenzene and/or ortho-dichlorobenzene.
